(19) United States
(12) Patent Application Publication
(10) Pub. No.: US 2024/0356255 A1
(43) Pub. Date: Oct. 24, 2024

(54) ARRAY OF COMPLIANT CONNECTORS FOR ELECTRONIC ASSEMBLIES

(71) Applicant: Tesla, Inc., Austin, TX (US)

(72) Inventors: Rishabh Bhandari, San Carlos, CA (US); Yong guo Li, Gilroy, CA (US); Mohamed Haitham Helmy Nasr, Sunnyvale, CA (US); Samuel Lichy, San Jose, CA (US); Aydin Nabovati, Toronto (CA); Shiva Farzinazar, Santa Clara, CA (US); Mitchell Heschke, Los Altos Hills, CA (US)

(21) Appl. No.: 18/683,758

(22) PCT Filed: Aug. 12, 2022
(86) PCT No.: PCT/US2022/040204

§ 371 Date: Feb. 14, 2024

Related U.S. Application Data
(60) Provisional application No. 63/260,386, filed on Aug. 18, 2021.

(51) Int. Cl. H01R 12/71; H01R 13/24; H01R 13/46; H05K 7/20

(52) U.S. Cl. CPC H01R 12/716; H01R 13/2421; H01R 13/46; H05K 7/20927

(57) ABSTRACT

An array of compliant connectors for electronic assemblies is provided. In one aspect, a system includes an array of first electronic components and an array of second electronic components. Each of the second electronic components is paired with corresponding to one of the first electronic components. Each pair of the first and second electronic components is coupled via a plurality of compliant connectors.

### CROSS-REFERENCE TO RELATED APPLICATION

This application claims the benefit of U.S. Provisional Patent Application No. 63/260,386, titled “ARRAY OF POGO PINS FOR ELECTRONIC ASSEMBLIES,” filed Aug. 18, 2021, the disclosure of which is incorporated herein by reference in its entirety and for all purposes.

### BACKGROUND

### Technological Field

The present disclosure relates generally to connectors used to provide conductivity between sub-assemblies, and more specifically to compliant connectors for delivering signals and/or power.

### Description of the Related Technology

Electronic system assemblies can include a plurality of components such as a system on chip (SOC), an application-specific integrated circuit (ASIC), printed circuit board assembly (PCBA) etc., which may be connected to provide for electrical, thermal, and/or communication conductivity. Traditional implementation of board to board connectors typically do not work with high tolerances desired for some electronic assemblies. Other implementations of compliant connectors can be used but they can be hard to assemble, have much higher tolerance and strain on the board.

### SUMMARY OF CERTAIN INVENTIVE ASPECTS

In one aspect, there is provided a system, comprising: an array of first electronic components; and an array of second electronic components, each of the second electronic components paired a corresponding one of the first electronic components, wherein each pair of the first and second electronic components is coupled via a plurality of compliant connectors.

In some embodiments, each of the first and second electronic components comprises a plurality of compliant connector pads on at least one side of the electronic component, and each of the compliant connectors is configured to contact one of the compliant connector pads.

In some embodiments, at least one of the compliant connector pads is connected to a plurality of the compliant connectors.

In some embodiments, the system further comprises: a plurality of compliant connector housings, each of the compliant connector housings configured to house a subset of the compliant connectors.

In some embodiments, the system further comprises: an intermediate plate, wherein the first electronic components are arranged on a first side the intermediate plate and the second electronic components are arranged on a second side the intermediate plate, the second side being opposite to the first side, wherein the intermediate plate has a plurality of openings therethrough, and wherein each of the compliant connector housings is configured to be press-fit into one of the openings of the intermediate plate.

In some embodiments, each of the compliant connector housings comprises a plurality of ribs configured to be deformed when the respective compliant connector housing is inserted into one of the openings.

In some embodiments, the intermediate plate comprises a cold plate configured to cool the first and second electronic components and the compliant connectors, and a thermal epoxy is provided between the compliant connector housings and the cold plate to provide for additional thermal cooling of the compliant connectors.

In some embodiments, at least some of the openings are configured to receive two compliant connector housings.

In some embodiments, the two compliant connector housings in a same opening house respective groups of compliant connectors configured to couple different pairs of the first and second electronic components.

In some embodiments, the compliant connectors are arranged in pairs such that a first one of the pair of compliant connectors is configured to the first electronic component of the corresponding pair of the first and second electronic components and a second one of the pair of compliant connectors is configured to contact the second electronic component of the corresponding pair of the first and second electronic components.

In some embodiments, each of the compliant connector housings comprises a pair of springs for each pair of compliant connectors, and the springs in the compliant connector housing provide two-way floating such that force applied to each of the compliant connectors is independent of force applied to other ones of the compliant connectors.

In some embodiments, the compliant connectors in each of the compliant connector housings are arranged to form a two-dimensional array.

In some embodiments, the compliant connectors are further configured to provide electrical, thermal, and/or communication conductivity between a corresponding pair of the first and second electronic components.

In some embodiments, the first electronic components are voltage regulating modules (VRMs) and the second electronic components are circuits on a printed circuit board.

In some embodiments, the compliant connectors comprise pogo pins.

In another aspect, there is provided a system, comprising: an array of first electronic components; and a plurality of compliant connector assemblies, each of the compliant connector assemblies comprising a group of compliant connectors and a housing around the group of compliant connectors, wherein each of the first electronic components comprises one or more pads electrically connected to at least one of the groups of compliant connectors of a respective compliant connector assembly of the compliant connectors assemblies.

In some embodiments, the system further comprises: a cold plate arranged on one side of the array of first electronic components, the cold plate configured to cool the first electronic components and having a plurality of openings therethrough, wherein each of the housings is configured to be press-fit into one of the openings of the cold plate.

In some embodiments, the system further comprises: a control board arranged with the cold plate positioned between the array of first electronic components and the control board, wherein the compliant connectors are configured to electrically connect the first electronic components to the control board and the control board is configured to provide power and/or control signals to the first electronic components.

In some embodiments, the system further comprises: a control board having an array of second electronic components thereon, wherein the compliant connectors electrically connect the first electronic components to the second electronic components.

In some embodiments, the compliant connectors comprise pogo pins.

In yet another aspect, there is provided an electronic system, comprising: an array of integrated circuit dies; an array of voltage regulating modules arranged over the array of integrated circuit dies; a printed circuit board comprising a plurality of groups electrical contacts; and compliant connectors comprising groups of compliant connectors, each group of compliant connectors electrically connecting a voltage regulating module of the array of voltage regulating modules to a respective group of electrical contacts on the printed circuit board.

In some embodiments, the electronic system further comprises: a plurality of compliant connector housings, each of the compliant connector housings configured to house an individual group of the groups of compliant connectors.

In some embodiments, the electronic system further comprises: a cold plate positioned between the array of voltage regulating modules and the printed circuit board, wherein each of the compliant connector housing extends through a respective opening of the cold plate.

In some embodiments, each of the compliant connector housings comprises a plurality of ribs configured to be deformed when the compliant connector housing is inserted into one of the openings.

In some embodiments, at least some of the openings of the cold plate have two pogo pin housings extending therethrough, and groups of pogo pins within the two pogo pin housings each electrically connected to a different voltage regulating module.

In some embodiments, the compliant connectors comprise pogo pins.

### BRIEF DESCRIPTION OF THE DRAWINGS

FIG. 1A shows a schematic cross sectional side view of a system on a wafer (SoW) assembly with pogo pins according to an embodiment.

FIG. 1B illustrates an electronic sub-system assembly having a plurality of groups of pogo pins in accordance with aspects of this disclosure.

FIGS. 2A-2D illustrate various views of an electronic system assembly including the electronic system sub-assembly of FIG. 1B.

FIG. 3 illustrates a cross-section of line 3-3 from FIG. 2D.

FIG. 4 illustrates a cross-section of line 4-4 from FIG. 2D including an internal structure of the pogo pin housing.

FIG. 5 illustrates another embodiment of a portion of an electronic system sub-assembly having a plurality of groups of pogo pins in accordance with aspects of this disclosure.

### DETAILED DESCRIPTION

The following detailed description of certain embodiments presents various descriptions of specific embodiments. However, the innovations described herein can be embodied in a multitude of different ways, for example, as defined and covered by the claims. In this description, reference is made to the drawings where like reference numerals and/or terms can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings. The headings provided herein are for convenience only and are not intended to affect the meaning or scope of the claims.

### Electrical Connections in Electronic Assemblies

Aspects of this disclosure relate to connectors or other coupling devices that can be used to electrically connect two or more sub-assemblies of an electronic system assembly. Depending on the application, an example electronic system assembly can include a plurality of electronic components which include electrical, thermal, and/or communication conductivity therebetween. Example electronic components include without limitation: a system on chip (SOC), an application-specific integrated circuit (ASIC), printed circuit board assembly (PCBA), etc.

In order to reduce the size of the electronic system, two or more of the electronic components may be stacked vertically and thus occupy substantially the same footprint. As the overall size of the electronic components as well as the size of the individual contact points is reduced, the tolerances for the connectors used to electrically connect the electronic components become tighter. It can be difficult to use traditional connectors (e.g., soldered connections) while meeting the tolerances of electronic components for certain applications.

### Compliant Connectors

Aspects of this disclosure relate to the use of compliant connectors that can be used to connect electronic devices within an electronic system assembly. While portions of this disclosure describe the use of pogo pins as an example compliant connector, this disclosure is not limited thereto and any suitable compliant connector can be used in accordance with any suitable principles and advantages of this disclosure. The references to pogo pins in this disclosure and in the figures are provided for illustrative purposes. Examples of compliant connectors which may be suitable for connecting electronic devices in accordance with aspects of this disclosure include without limitation: pogo pins, flexible pins, spring contacts, etc.

Aspects of this disclosure relate to pogo pin connectors, which can provide various advantage over other connectors. For many applications, electronic components are electrically connected using bond wires, or other conductive materials that are soldered to pads on the electronic components. In addition to this type of soldering being time consuming, as the dimensions of the electronic components and/or connector pads formed therein decrease, it is becoming increasingly difficult to accurately solder connectors to the corresponding pads without introducing soldering errors. Typical board to board connections may not work for relatively high tolerance applications.

Pogo pins are a type of connector that can be used in certain applications, such as testing electronic components during production. A pogo pin is a type of electrical connector that is spring loaded. Pogo pins can be used to connect electronic components, but there have been technical challenges with using pogo pins in assembling electronic systems.

Advantageously, pogo pins have much higher tolerance and lower strain on the electronic components compared to a number of other connector technologies. Using pogo pins for electrical, thermal, and/or communication conductivity connections between electronic components within a product as described herein can have a number of additional advantages. For example, in one aspect, the arrangement of pogo pins including structural support to pins to make it easier to package, ship, and use a system without damaging the pogo pins. In another aspect, the arrangement of pogo pins can provide for ease of assembly by removing soldering of parts and making the pogo pins independent of the connected electronic components. In another aspect, the arrangement of pogo pins can provide for more accurate alignment of the pins and corresponding pads, including minimal angular error below threshold amounts.

In still further aspects, the arrangement of the housings for the pogo pins can push the housings towards a cold plate, and thus, reduce the contact resistance while assembling the pogo pins. In still another aspect, the pogo pin housing can incorporate a two-way floating pin design to reduce forces and strain on both connected electronic components by balancing the force and tolerance from two sides. This allows for a reduced contact resistance and heat generation in the pins while also minimizing overall board strain.

In still further aspects, the arrangement of pogo pins provides for cooling of the pins, which can be improved by adding thermal grease between the pins and the cold plate and by insert molding the pogo pin housing (e.g., cartridge) in the cold plate to reduce contact resistance.

Aspects of this disclosure can also be used for any board to board signal transmission where high current or a high number of signals are implemented. The technology disclosed herein is particularly well suited to applications with relatively small space on the electrical component(s) for connections while also having a relatively large overall footprint. In certain aspects, the pogo pins can be formed of highly conductive materials (e.g., Cu alloys). The cartridge can be a material that can achieve high electrical resistance and good thermal conductivity

One skilled in the relevant art will appreciate that individual implementations of the arrangement of pogo pins in accordance with aspects of the present application can involve the satisfaction of all or any of the identified benefits. Additionally, further benefits may also be realized with one or more embodiments of the present application.

Pogo pins can electrically connect electronic components of a first array of electronic components and electronic components of a second array of electronic components. One example application of electronic components that can be connected by pogo pins is an array of voltage regulating modules (VRMs) and an array of circuits on a control printed circuit board (also referred to as a control board). In addition, aspects of this disclosure can also be used to connect other suitable combinations of electronic components, including but not limited to: a printed circuit board to a wafer, a printed circuit board to a panel, two printed circuit boards together, a first array of VRMs to a second array of VRMs, etc.

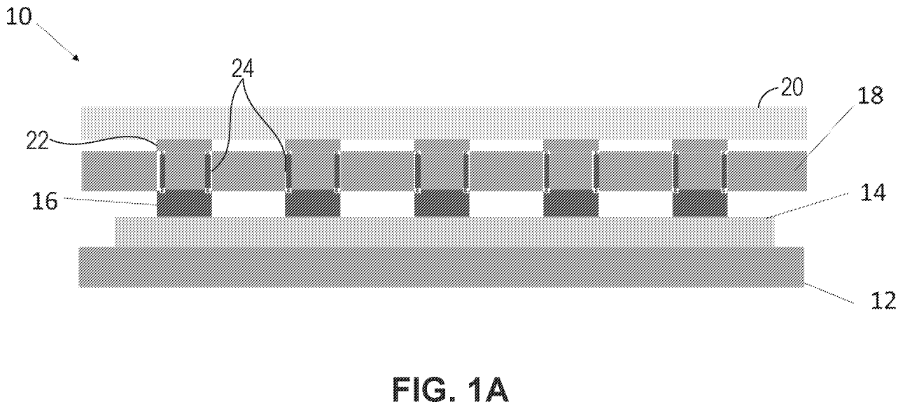

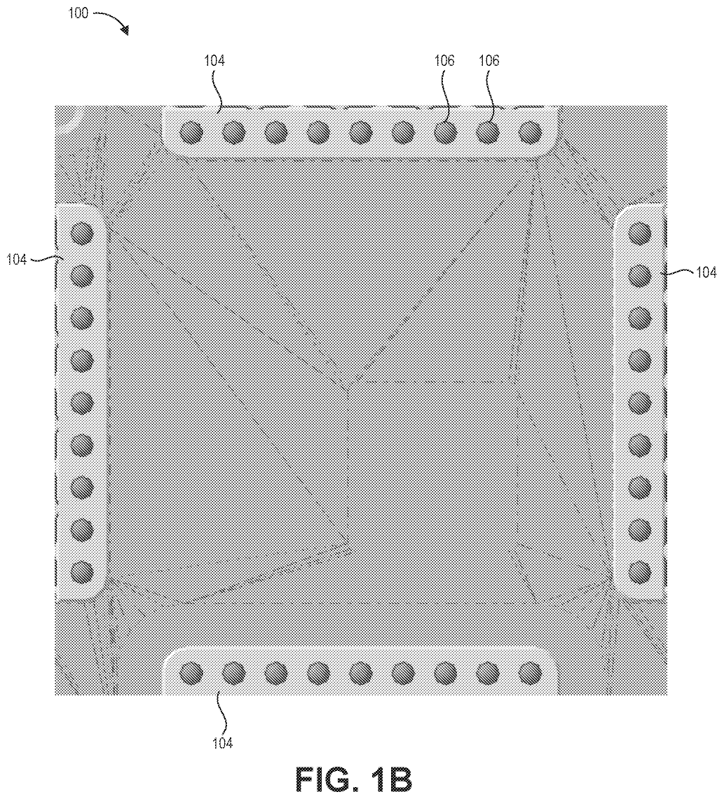

FIG. 1A shows a schematic cross sectional side view of a system on a wafer (SoW) assembly 10 after coupling an intermediate plate 18 (such as a cold plate) with voltage regulating modules (VRMs) 16 on a SoW 14 on one side and a control board 20 on another side. As illustrated in FIG. 1A, the SoW assembly 10 includes a cooling component 12, the SoW 14, VRMs 16, the intermediate plate 18, and the control board 20. The SoW 14 can include an array of integrated circuit dies. The array of VRMs 16 are one example of an array of electronic components that can be arranged as shown in FIG. 1A. The arrangement of FIG. 1A can be applied to a variety of different electronic components.

The control board 20 can include an array of electronic components 22. The electronic components 22 can be control circuits, each configured to control a corresponding one of the VRMs 16. For example, the electronic components 22 can be configured to provide power and/or control signals to the corresponding VRMs 16 to operate the VRMs 16. The intermediate plate 18 can include a plurality of openings with pogo pins 24 therein.

The pogo pins 24 can electrically connect the control board 20 to the VRMs 16. For example, each of the openings can be configured to receive a plurality of pogo pins 24, which may be housed in a housing such as a cartridge. The pogo pins 24 can be configured to connect electric components arranged on opposite sides of the intermediate plate 18 in order to provide power and/or control signals therebetween. The pogo pins 24 can be implemented in accordance with any suitable principles and advantages disclosed herein. The pogo pins disclosed herein can connect any suitable arrays of electronic components.

One or more aspects of the present disclosure relate to the utilization of an arrangement of pogo pins to provide signal, thermal, and/or communication connectivity to sub-assemblies of an electronic assembly. In particular, FIG. 1B illustrates an electronic sub-system assembly 100 having a plurality of groups of pogo pins in accordance with aspects of this disclosure.

With reference to FIG. 1B, the electronic system sub-assembly 100 and a plurality pogo pin housings 104 (also referred to as “cartridges”). Each of the housings 104 can house a plurality of the pogo pins 106 and aid in aligning the pogo pins 106 with corresponding pads on electronic component(s) as discussed herein. Advantageously, by using the pogo pin housings 104 in accordance with aspects of this disclosure, it can be easier to package, ship, and use pogo pins 106 without damaging the pogo pins 106 by providing structural support to the pogo pins 106. For example, the pogo pin housings 104 can prevent the pogo pins 106 from being bent during shipping and handling. Thus, the pogo pin housings 104 can provide sufficient stability and alignment for the pogo pins 106 in accordance with aspects of this disclosure.

The pogo pins 106 can be arranged between electronic components located on opposite sides of the pogo pins 106. In the illustrated embodiment, each housing 104 is arranged along the edge of the sub-assembly 100. FIG. 1B illustrates an electronic system sub-assembly 100 having an arrangement of 36 pogo pins 106. The arrangement of pogo pins 106 includes four distinct sub-arrangements of 9 pogo pins 106 on each of the four edges of the electronic system sub-assembly. However, aspects of this disclosure are not limited to the arrangement of FIG. 1B and there may be more or fewer groups, more or fewer pogo pins 106, and the groups of pogo pins 106 may be arranged in different locations with respect to the sub-assembly. Advantageously, by using pogo pins 106 to connect electronic components, the assembly of the electronic system sub-assembly 100 is simplified by removing the need to solder parts accurately while ensuring the soldered points are independent of the connected electronic components. The pogo pins 106 additionally provide more accurate alignment with pads on the electronic components than soldered connectors.

Depending on the implementation, the pogo pins 106 can be further arranged in accordance with a repeatable pattern that can be scaled based on one or more of the power, thermal, or communication specifications of the electronic system sub-assembly 100. Illustratively, the arrangement of pogo pins 106 can be utilized specifically in the context of intermediate plate (e.g., a cold plate) of the electronic system assembly.

The pogo pins 106 are configured to couple (e.g., provide electrical, thermal, and/or communication conductivity) electronic component(s) (not illustrated) arranged above and below the pogo pins 106. The pogo pin housings 104 are configured to align the individual pogo pins 106 with corresponding contacts (e.g., pads) formed on the electronic components.

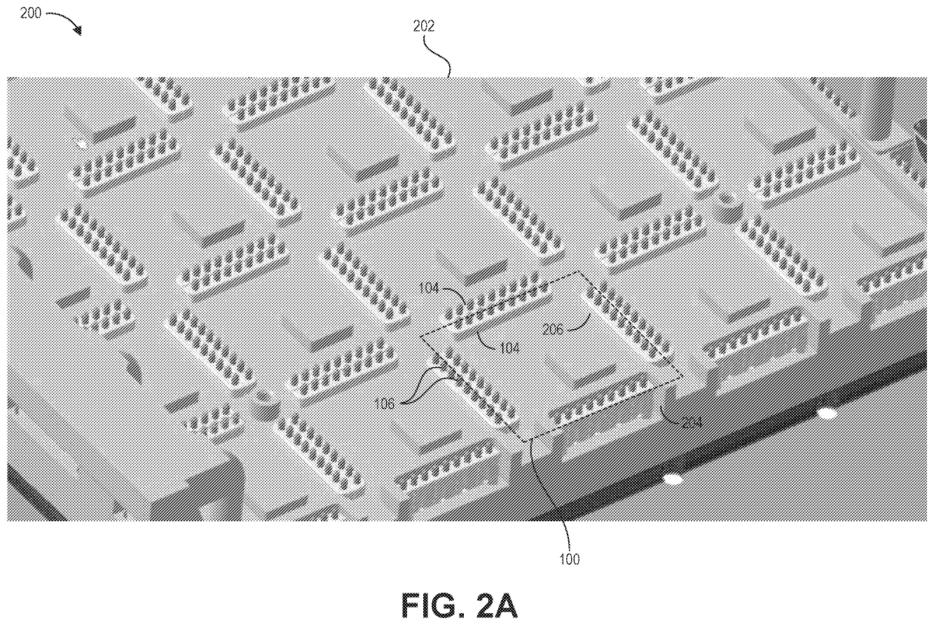

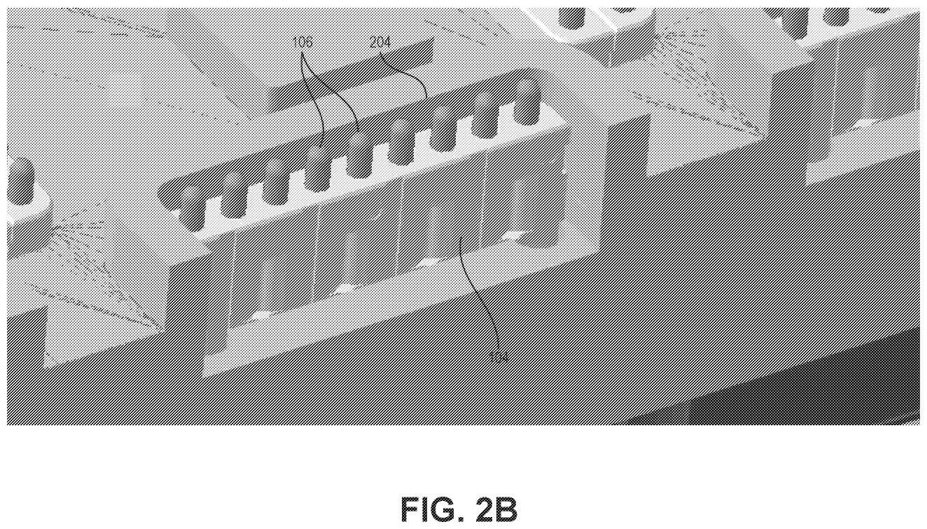

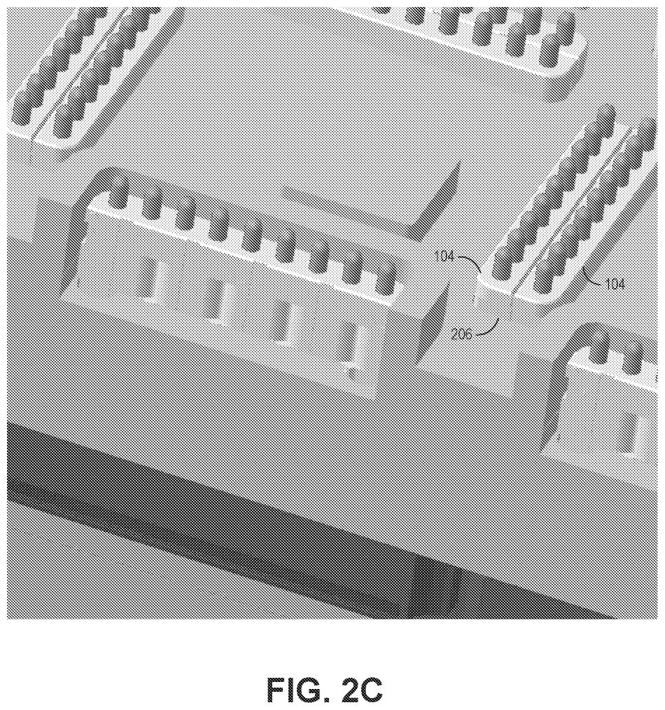

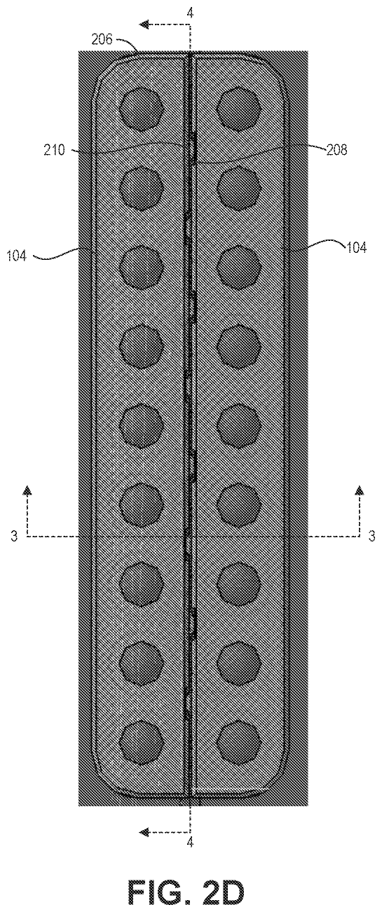

FIGS. 2A-2D illustrate a number of views of an electronic system assembly 200 including the electronic system sub-assembly 100 of FIG. 1B. In particular, FIG. 2A illustrates an arrangement of pogo pin housings 104 with respect to an intermediate plate 202 (such as a cold plate) in accordance with aspects of this disclosure. FIG. 2B provides a closeup view of an opening 204 (e.g., a slot) in the intermediate plate 202 in which a pogo pin housing 104 is inserted in accordance with aspects of this disclosure. FIG. 2C illustrates another opening 204 in which two pogo pin housings 104 are inserted in accordance with aspects of this disclosure. FIG. 2D is a plan view of two pogo pin housings 104 arranged within a corresponding opening 204.

With reference to FIG. 2A, the electronic system assembly 200 includes the intermediate plate 202 formed between a plurality of pairs of electronic components. The electronic system assembly 200 further includes an array of the electronic sub-assemblies 100 illustrated in FIG. 1B. Each sub-assembly 100 can be configured to couple a pair of electronic components arranged on opposite sides of the pogo pins 106. Thus, an array of electronic component pairs can be connected via the pogo pins 106 included in the electronic system assembly 200. To provide electrical connections to each electronic component of an array, a relatively large number of pogo pins can be used. Features of the pogo pin assemblies disclosed herein can contribute to overcoming technical challenges related to manufacturing time and alignment in making a large number of electrical connections in a relatively tight physical area for such electronic component arrays. For example, there can be hundreds of pogo pins in the electronic system assembly 200 in certain applications. There can be over 1000 pogo pins in the electronic system assembly 200 in some application. The use of the pogo pin housings 104 described herein can make the processes of assembling the pogo pins 106 in the electronic system assembly 200 repeatable and faster than using other connector types. The intermediate plate 202 further includes a plurality of openings 204, 206 formed therein. Each opening 204, 206 is configured to receive one or more pogo pin housings 104. The intermediate plate 202 can be a cold plate, for example.

The opening 204 shown in FIG. 2B is configured to receive a single pogo pin housing 104. In some implementations, the opening 204 of FIG. 2B may be located at an edge of the electronic system assembly 200 such that the pogo pins 106 arranged in the opening couple one pair of electronic components.

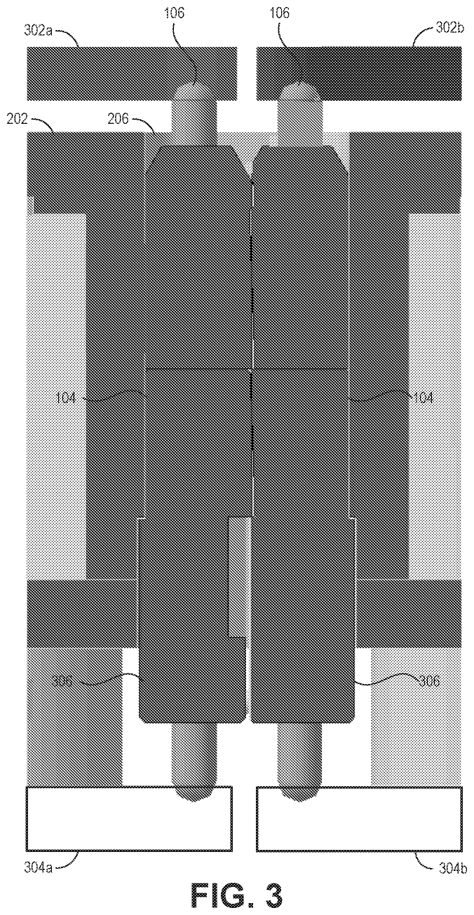

As shown in FIGS. 2C and 2D, the opening 206 is configured to receive two pogo pin housings 104. The pogo pins 106 in each of the respective pogo pin housings 104 can be configured to couple a different pair of electronic components. That is, the edges of an adjacent pair of electronic components may substantially align with the interface between the pair of pogo pin housings 104 received in the opening 206. As discussed in connection with FIG. 3, by inserting two pogo pin housings 104 into a single opening 206, the pogo pin housings 104 can push against another to fit within the opening 206. The pogo pin housings 104 can be designed with one side having a shape is complementary to the same side on another pogo pin housing 104. For example, the complementary sides may have interlocking grooves 208 and ridges 210 that align the pogo pin housings 104 together.

In some embodiments, the pogo pin housings 104 may be shaped such that they can fit into either type of opening 204 or 206. For example, a single pogo pin housing 104 can be press fit into the opening 204 as shown in FIG. 2B or a pair of the pogo pin housings 104 can be fit into the opening 206 shown in FIGS. 2C and 2D. Accordingly, it is not necessary to design different pogo pin housings 104 based on the opening into which the pogo pin housings 104 are inserted.

The openings 204, 206 together with the pogo pin housings 104 are configured to provide a sufficient level of perpendicularity for the pogo pins 106 to contact each of the contact points on the electronic components. In some embodiments, the openings 204, 206 and the pogo pin housings 104 can provide perpendicularity within, for example, 0.3 degrees, 0.4 degrees, 0.5 degrees, 0.6 degrees, 0.7 degrees, or the like. However, other amounts of perpendicularity can be provided depending on the implementation.

FIG. 3 illustrates a cross-section of line 3-3 from FIG. 2D. As shown in FIG. 3, the pogo pins 106 are configured to contact one of first electronic components 302a, 302b arranged above the intermediate plate 202 and one of second electronic components 304a, 304b arranged below the intermediate plate 202. The pogo pin housings 104 can be press-fit into the opening 206 formed in the intermediate plate 202. Further, each of the pogo pin housings 104 includes one or more ribs 306. The ribs 306 can be deformed when the pogo pin housings 104 are inserted into the opening 206, securing the pogo pin housings 104 in place. Thus, the pogo pin housings 104 can create forces against each other and the opening 206 to aid in securing the pogo pins 106.

In some embodiments, the pogo pin housings 104 and ribs 306 may be formed of molded plastic while the intermediate plate 202 is formed of metal to facilitate the deforming of the ribs 306 when the pogo pin housings 104 are inserted into the openings 204, 206. The ribs 306 may be crushed upon insertion of the pogo pin housings 104 into the openings 204, 206 in order to aid in securing the pogo pin housings 104 in the corresponding openings 204, 206. In some implementations, each the pogo pin housing 104 may be molded in two pieces which are combined together to form the body of the pogo pin housing 104. In some implementations, the selection of the material for pogo pins 106 and the pogo pin housings 104 can further provide electrical isolation of greater than 10¹³ ohms while providing a thermal conductance of greater than 1 W/mK. However, these are merely exemplary values and other materials may provide greater or lesser amounts of electrical isolation and thermal conductance.

In accordance with aspects of the present application, the pogo pins 106 can be arranged such that individual pogo pins 106 create forces against each other within the pogo pin housing 104. This can reduce contact resistance, especially in embodiments in which the arrangement of pogo pins 106 are utilized to adhere to an intermediate plate 202.

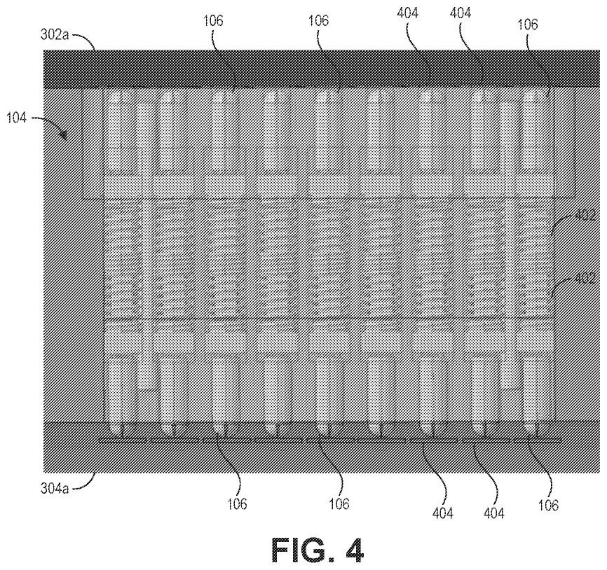

FIG. 4 illustrates a cross-section of line 4-4 from FIG. 2D including an internal structure of the pogo pin housing 104. In the illustrated embodiment, the pogo pin housing 104 can include a pair of springs 402 for each pair of pogo pins 106. Accordingly, the pogo pin housing 104 provides two-way floating such that force applied to each of the individual pogo pins 106 is independent of the force applied to other pogo pins 106. In some implementations, the two-way floating design of the pogo pin housing 104 can provide a substantially constant force on each of the electronic components 302a, 304a. The two-way floating design also allows for relatively smaller pogo pins 106 to absorb higher tolerances and the illustrated spring design facilitates the absorbing of balancing forces automatically.

In certain embodiments, such as for high current applications, additional cooling can be provided inserting the pogo pin housings 104 into openings in an intermediate plate 202 that is a cold plate. The cold plate can be configured to cool the electronic components 302a, 304a as well as the pogo pin housings 104 and pogo pins 106. A coolant flowing through the cold plate can implement active cooling. A press-fit solid shield can be utilized to provide cooling for the pogo pin housing 104 and pogo pins 106. In addition, a thermal epoxy may be provided to provide for additional thermal conduction/cooling of the pogo pin housings 104 and the pogo pins 106.

FIG. 4 also illustrates the pogo pin touch pads 404 (also referred to as “pads”) formed on a surface of each of the electronic components 302a, 304a. The pads 404 provide contact points at which the individual pogo pins 106 can contact the electronic components to form electrical, thermal, and/or communication conductivity paths between the electronic components 302a, 304a.

Although the pogo pins 106 are illustrated as having generally hemi-spherical or rounded ends, aspects of this disclosure are not limited thereto. For example, the pogo pins 106 may have sharper ends (e.g., conical) which can better puncture or penetrate through debris or other contaminants located on the pogo pin touch pads 404.

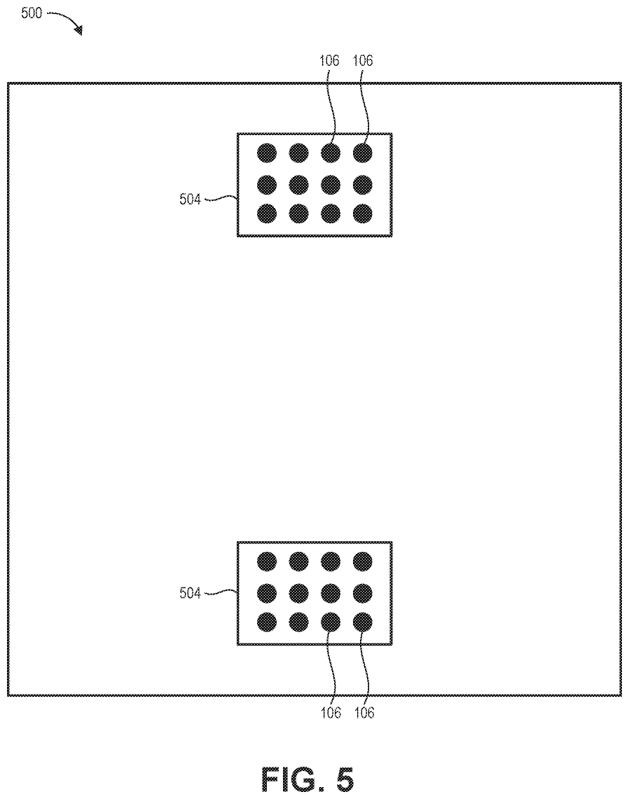

FIG. 5 illustrates another embodiment of a portion of an electronic system sub-assembly 500 having a plurality of groups of pogo pins in accordance with aspects of this disclosure. In contrast to the embodiment of FIG. 1B, the pogo pin housings 504 are located away from the edges of the sub-assembly 500 and include a two-dimensional array of pogo pins 106. In addition, by providing a higher number of pogo pins 106 per pogo pin housing 504, the number of housings 504 can be reduced compared to the embodiment shown in FIG. 1B. Moreover, in some implementations such as in FIG. 5, each opening may receive a single pogo pin housing 504.

In some embodiments, the pogo pins 106 may have varying diameters depending on the functionality of the pogo pin 106. For example, certain electronic components, such as VRMs, may consume relatively large amounts of power to operate at optimal parameters (e.g., for high density computer applications), while also using electrical connections for less power intensive control signals. Such applications may have a limited area to cool hot components while at the same time involve passing many signals and power. The amount of power that can be provided by a pogo pin 106 may be limited by the resistance of the pogo pin 106, which is related to the pogo pin's 106 diameter. Thus, the pogo pins 106 used to provide power to an electronic component may have a larger diameter than other pogo pins 106 housed within the pogo pin housing 504 (or within the housing 104).

In some implementations, in place of or in addition to using larger diameter pogo pins 106, a plurality of pogo pins 106 may be connected to a single pad 404 such that the plurality of pogo pins 106 can provide a greater amount of power to the pad 404. Alternatively, the plurality of pogo pins 106 providing the same voltage may be connected to a plurality of pads 404 which are electrically connected within the VRM.

The number of pogo pins 106 illustrated in each pogo pin housing 504 are not necessarily shown to scale in FIG. 5. In example embodiments, the number of pogo pins 106 may be 26 or 36 for each sub-assembly 500, however, any suitable number of pogo pins 106 can be included depending on the design of the sub-assembly 500 (or the sub-assembly 100).

### Conclusion

The foregoing disclosure is not intended to limit the present disclosure to the precise forms or particular fields of use disclosed. As such, it is contemplated that various alternate embodiments and/or modifications to the present disclosure, whether explicitly described or implied herein, are possible in light of the disclosure. Having thus described embodiments of the present disclosure, a person of ordinary skill in the art will recognize that changes may be made in form and detail without departing from the scope of the present disclosure. Thus, the present disclosure is limited only by the claims.

In the foregoing specification, the disclosure has been described with reference to specific embodiments. However, as one skilled in the art will appreciate, various embodiments disclosed herein can be modified or otherwise implemented in various other ways without departing from the spirit and scope of the disclosure. Accordingly, this description is to be considered as illustrative and is for the purpose of teaching those skilled in the art the manner of making and using various embodiments of the disclosed press-fit connectors assembly. It is to be understood that the forms of disclosure herein shown and described are to be taken as representative embodiments. Equivalent elements, materials, processes or steps may be substituted for those representatively illustrated and described herein. Moreover, certain features of the disclosure may be utilized independently of the use of other features, all as would be apparent to one skilled in the art after having the benefit of this description of the disclosure. Expressions such as “including”, “comprising”, “incorporating”, “consisting of”, “have”, “is” used to describe and claim the present disclosure are intended to be construed in a non-exclusive manner, namely allowing for items, components or elements not explicitly described also to be present. Reference to the singular is also to be construed to relate to the plural.

Further, various embodiments disclosed herein are to be taken in the illustrative and explanatory sense, and should in no way be construed as limiting of the present disclosure. All joinder references (e.g., attached, affixed, coupled, connected, and the like) are only used to aid the reader's understanding of the present disclosure, and may not create limitations, particularly as to the position, orientation, or use of the systems and/or methods disclosed herein. Therefore, joinder references, if any, are to be construed broadly. Moreover, such joinder references do not necessarily infer that two elements are directly connected to each other. Additionally, all numerical terms, such as, but not limited to, “first”, “second”, “third”, “primary”, “secondary”, “main” or any other ordinary and/or numerical terms, should also be taken only as identifiers, to assist the reader's understanding of the various elements, embodiments, variations and/or modifications of the present disclosure, and may not create any limitations, particularly as to the order, or preference, of any element, embodiment, variation and/or modification relative to, or over, another element, embodiment, variation and/or modification.

It will also be appreciated that one or more of the elements depicted in the drawings/figures can also be implemented in a more separated or integrated manner, or even removed or rendered as inoperable in certain cases, as is useful in accordance with a particular application.

1. A system, comprising:
an array of first electronic components;
an array of second electronic components, each of the second electronic components paired a corresponding one of the first electronic components; and
a plurality of compliant connector housings, each of the compliant connector housings housing a plurality of compliant connectors configured to electrically couple a corresponding pair of the first and second electronic components.

2. The system of claim 1, wherein:
each of the first and second electronic components comprises a plurality of compliant connector pads on at least one side of the electronic component, and
each of the compliant connectors is configured to contact one of the compliant connector pads.

3. The system of claim 2, wherein at least one of the compliant connector pads is connected to a plurality of the compliant connectors.

4. (canceled)

5. The system of claim 1, further comprising:
an intermediate plate, wherein the first electronic components are arranged on a first side the intermediate plate and the second electronic components are arranged on a second side the intermediate plate, the second side being opposite to the first side,
wherein the intermediate plate has a plurality of openings therethrough, and
wherein each of the compliant connector housings is configured to be press-fit into one of the openings of the intermediate plate.

6. The system of claim 5, wherein each of the compliant connector housings comprises a plurality of ribs configured to be deformed when the respective compliant connector housing is inserted into one of the openings.

7. The system of claim 5, wherein:
the intermediate plate comprises a cold plate configured to cool the first and second electronic components and the compliant connectors, and
a thermal epoxy is provided between the compliant connector housings and the cold plate to provide for additional thermal cooling of the compliant connectors.

8. The system of claim 5, wherein at least some of the openings are configured to receive two compliant connector housings.

9. The system of claim 8, wherein the two compliant connector housings in a same opening house respective groups of compliant connectors configured to couple different pairs of the first and second electronic components.

10. The system of claim 1, wherein the compliant connectors are arranged in pairs such that a first one of the pair of compliant connectors is configured to the first electronic component of the corresponding pair of the first and second electronic components and a second one of the pair of compliant connectors is configured to contact the second electronic component of the corresponding pair of the first and second electronic components.

11. The system of claim 10, wherein:
each of the compliant connector housings comprises a pair of springs for each pair of compliant connectors, and
the springs in the compliant connector housing provide two-way floating such that force applied to each of the compliant connectors is independent of force applied to other ones of the compliant connectors.

12. The system of claim 1, wherein the compliant connectors in each of the compliant connector housings are arranged to form a two-dimensional array.

13. The system of claim 1, wherein the compliant connectors are further configured to provide electrical, thermal, and/or communication conductivity between a corresponding pair of the first and second electronic components.

14. The system of claim 1, wherein the compliant connectors comprise pogo pins.

15. A system, comprising:
an array of first electronic components; and
a plurality of compliant connector assemblies, each of the compliant connector assemblies comprising a group of compliant connectors and a housing around the group of compliant connectors,
wherein each of the first electronic components comprises one or more pads electrically connected to at least one of the groups of compliant connectors of a respective compliant connector assembly of the compliant connector assemblies.

16. The system of claim 15, further comprising:
a cold plate arranged on one side of the array of first electronic components, the cold plate configured to cool the first electronic components and having a plurality of openings therethrough,
wherein each of the housings is configured to be press-fit into one of the openings of the cold plate.

17. The system of claim 16, further comprising:
a control board arranged with the cold plate positioned between the array of first electronic components and the control board,
wherein the compliant connectors are configured to electrically connect the first electronic components to the control board and the control board is configured to provide power and/or control signals to the first electronic components.

18. The system of claim 16, further comprising:
a control board having an array of second electronic components thereon,
wherein the compliant connectors electrically connect the first electronic components to the second electronic components.

19. The system of claim 15, wherein the compliant connectors comprise pogo pins.

20. An electronic system, comprising:
an array of integrated circuit dies;
an array of voltage regulating modules arranged over the array of integrated circuit dies;
a printed circuit board comprising a plurality of groups electrical contacts; and
a plurality of compliant connector housings, each of the compliant connector housings configured to house a group of compliant connectors, each group of compliant connectors electrically connecting a voltage regulating module of the array of voltage regulating modules to a respective group of electrical contacts on the printed circuit board.

21. (canceled)

22. The electronic system of claim 20, further comprising:
a cold plate positioned between the array of voltage regulating modules and the printed circuit board,
wherein each of the compliant connector housings extends through a respective opening of the cold plate.

23. The electronic system of claim 22, wherein each of the compliant connector housings comprises a plurality of ribs configured to be deformed when the compliant connector housing is inserted into one of the openings.

24. The electronic system of claim 20, wherein the compliant connectors comprise pogo pins.
